(19) United States
(12) Patent Application Publication
(10) Pub. No.: US 2024/0188418 A1
(43) Pub. Date: Jun. 6, 2024

(54) Core/shell quantum dot for Light-Emitting Diode and Preparation Method therefor, and Light-Emitting Diode

(71) Applicant: SUZHOU XINGSHUO NANOTECH CO., LTD., Suzhou, Jiangsu (CN)

(72) Inventors: Yuliang SHAN, Suzhou, Jiangsu (CN); Yunjun WANG, Suzhou, Jiangsu (CN)

(21) Appl. No.: 18/284,871

(22) PCT Filed: Dec. 30, 2021
(86) PCT No.: PCT/CN2021/143412

§ 371 Date: Sep. 29, 2023

(30) Foreign Application Priority Data
May 10, 2021 (CN) 202110505210.6

(51) Int. Cl. H10K 85/30; B82Y 20/00; B82Y 40/00; C09K 11/02; C09K 11/08; C09K 11/70; C09K 11/88; H10K 50/115

(52) U.S. Cl. CPC H10K 85/381; C09K 11/025; C09K 11/0883; C09K 11/703; C09K 11/883; B82Y 20/00; B82Y 40/00; H10K 50/115

(57) ABSTRACT

The present disclosure provides a core/shell quantum dot for a Light-Emitting Diode (LED) and a preparation method therefor, and an LED. The core/shell quantum dot includes a core body and a surface shell; and the surface shell is ZnS₁₋ₓOₓ, wherein 0.1≤x≤0.9. The core-shell quantum dot of the present disclosure can significantly improve the current density, brightness, and external quantum efficiency of the LED prepared therefrom.

This application is based upon and claims priority to Chinese Patent Application No. 202110505210.6 filed on May 10, 2021, the disclosure of which is hereby incorporated by reference in its entirety.

### TECHNICAL FIELD

The present application belongs to the technical field of nanometers, and specifically relates to a core/shell quantum dot for a Light-Emitting Diode (LED) and a preparation method therefor, and an LED.

### BACKGROUND

A Quantum dot Light-Emitting Diode (QLED) is a device that electrically excites quantum dots directly to emit light. Compared with a traditional Organic Light-Emitting Diode (OLED), the QLED has the characteristics of being more excellent in color purity and brightness, low in cost and good in stability. Quantum dots may be dispersed in an organic solvent, may be used to manufacture a light-emitting thin film by means of inkjet printing, spin coating and blade coating, and are suitable for panels with different sizes. Therefore, the QLED has a promising market prospect.

The common QLED generally includes, from bottom to top, a positive electrode, a hole transport layer, a quantum dot electroluminescent layer, an electron transport layer and a negative electrode. An external circuit separately injects electrons and holes into a device by means of the negative electrode and the positive electrode; and injected carriers reach the light-emitting layer by means of the electron transport layer and the hole transport layer, so as to achieve composite light emitting. The electron transport layer of the existing QLED uses zinc oxide, resulting in fast electron migration speed; and the hole transport layer uses an organic material, which is slow in hole migration speed, resulting in imbalance of the injected electrons and holes in the quantum dot electroluminescent layer, thereby causing defects of being low in efficiency and small in brightness. Therefore, there is an urgent need to optimize the quantum dots and change their conductivity, such that the electrons and the holes are better composited, thereby comprehensively improving the performance of the QLED.

### SUMMARY

In view of the above technical problems, the present application provides a core/shell quantum dot. The core/shell quantum dot includes a core body and a surface shell; and the surface shell is ZnS₁₋ₓOₓ, wherein 0.1≤x≤0.9.

Further, in ZnS₁₋ₓOₓ, 0.1≤x≤0.5.

Further, amass percentage of oxygen in the core/shell quantum dot does not exceed 1%.

Further, the surface shell is connected with surface ligand; and the surface ligand contains at least one of sulfhydryl, carboxyl, amino, amide, organophosphine, or organic ester.

The present application further provides a method for preparing a core/shell quantum dot for an LED. The method includes the following step.

At a certain temperature, a gas containing oxygen is introduced into dispersion liquid containing an initial quantum dot for reaction, so as to form a core/shell quantum dot. The initial quantum dot includes a core body and a ZnS shell layer coating outside the core body; the core/shell quantum dot comprises the core body and a surface shell; and the surface shell is ZnS₁₋ₓOₓ, wherein 0.1≤x≤0.9.

Further, the gas is air.

Further, the flow rate of the gas is 0.1-1 L/min, preferably 0.2-0.5 L/min.

Further, the temperature is 20-100° C., preferably 30-60° C.

Further, the dispersion liquid further contains a non-coordinating solvent, and the non-coordinating solvent is selected from at least one of an aliphatic solvent and/or an aromatic solvent.

Preferably, the non-coordinating solvent is selected from one or more of a group consisting of aliphatic hydrocarbon, aromatic hydrocarbon, chloroform, chlorobenzene, propylene glycol monomethyl ether acetate and hexanediol di-acrylate ester; the aliphatic hydrocarbon is selected from one or more of a group consisting of heptane, n-octane, hexane, 1-octadecene, octadecane and 1-hexadecene; and the aromatic hydrocarbon is selected from toluene and/or benzene. Preferably, the concentration of the initial quantum dot in the dispersion liquid is 10-100 mg/ml, more preferably 10-50 mg/mL.

The present application further provides an LED. The LED includes a quantum dot light-emitting layer. The quantum dot light-emitting layer includes the core/shell quantum dot for an LED described above, or includes a core/shell quantum dot obtained by the method for preparing an LED described above.

### Beneficial Effects are as Follows:

(1) The core/shell quantum dot of the present application includes the core body and the surface shell; and the surface shell is ZnS₁₋ₓOₓ, wherein 0.1≤x≤0.9. The structure may effectively improve the conductivity of the core/shell quantum dot, and the brightness and External Quantum Efficiency (EQE) of the LED obtained by means of preparation are greatly enhanced.

(2) According to the method for preparing a core/shell quantum dot of the present application, the air is used as an oxygen source to prepare the ZnS₁₋ₓOₓ surface shell, such that the preparation method is wide in raw material source, commonly available, non-toxic and harmless, simple in process, and green and environment-friendly, and has good economic and social benefits.

### BRIEF DESCRIPTION OF THE DRAWINGS

FIG. 1 is a surface energy spectrum analysis diagram of a core/shell quantum dot according to Embodiment 1 of the present application.

FIG. 2 is a scanning electron microscope diagram of a core/shell quantum dot according to Embodiment 1 of the present application.

FIG. 3 is a comparison diagram of voltage (V)-current density (A/m²) of an LED according to Embodiment 1 and Comparative example 1 of the present application.

FIG. 4 is a comparison diagram of voltage (V)-brightness (nit) of an LED according to Embodiment 1 and Comparative example 1 of the present application.

FIG. 5 is a comparison diagram of voltage (V)-EQE of an LED according to Embodiment 1 and Comparative example 1 of the present application.

### DETAILED DESCRIPTION OF THE EMBODIMENTS

The technical solutions in the embodiments of the present application are described below in detail with reference to the implementations of the present application. It should be noted that the implementations are only part of the implementations of the present application and not all of the implementations. If not otherwise defined, all terms in the specification (including technical and scientific terms) may be defined as commonly understood by those skilled in the art. Terms defined in generic dictionaries may be interpreted without idealization or exaggeration unless the terms are clearly defined. In addition, unless explicitly described to the contrary, the word “comprise” and variants such as “include” or “contain” are to be understood as meaning to include the stated elements (factors), but not to exclude any other elements (factors).

In the drawings, the thickness of layers, films, panels, areas, and the like is exaggerated for clarity. Throughout the specification, the same drawing signs indicate the same elements.

It is to be understood that, when an element (such as a layer, a film, an area, or a substrate) is described as being “on” another element, the element may be directly on that other element, or there may be an intermediate element. On the contrary, when the element is described as being “directly on” another element, there is no intermediate element.

In addition, unless otherwise mentioned, a singular form is also intended to include a plural form. As used herein, “a”, “one of”, “said (the)” and “at least one of . . . ” do not indicate quantitative limitations, but are intended to include both the singular form and the plural form, unless the context clearly indicates otherwise. For example, unless the context clearly indicates otherwise, “component (element)” has the same meaning as “at least one component (element)”. “At least one of” is not to be interpreted as limiting “a” or “one of”. The word “or” means “and/or”. As used herein, the term “and/or” includes any and all combinations of one or more of relevant listed items. It is to be further understood that, when the terms “include” and/or “comprise” or variations thereof are used in this specification, it indicates that there are stated features, regions, integral bodies, steps, operations, components and/or assemblies, but do not exclude the presence or addition of one or more other features, regions, integral bodies, steps, operations, components, assemblies and/or groups thereof.

It is to be understood that, the terms “first”, “second”, “third” and the like are used herein to describe various elements, components, areas, layers and/or portions, but these elements, components, areas, layers and/or portions are not limited by these terms. These terms are only used to distinguish one element, one component, one area, one layer or one portion from another.

As described in Background, electrons and holes injected in a quantum dot electroluminescent layer of a current common QLED are unbalanced, resulting in low quantum dot efficiency and small brightness of the QLED.

Based on this, the present application provides a core/shell quantum dot for an LED. The core/shell quantum dot includes a core body and a surface shell; and the surface shell is ZnS₁₋ₓOₓ, wherein 0.1≤x≤0.9. An outer surface of the surface shell of the quantum dot is distributed with three elements of oxygen, sulfur, zinc. The presence of the oxygen in the surface shell may effectively adjust the conductivity of the quantum dot, such that the electrons migrated from a negative electrode stay in the quantum dot light-emitting layer as much as possible and are efficiently combined with the holes, instead of entering a hole transport layer by passing through the quantum dot light-emitting layer, thereby significantly improving the light-emitting efficiency and brightness of the LED. Optionally, in ZnS₁₋ₓOₓ, x is selected from 0.16, 0.25, 0.32, 0.36, 0.44, 0.48, 0.72 or 0.78.

In the present application, the oxygen is doped in the surface of the quantum dot, such that the conductivity of the quantum dot is changed. By means of designing different ratios of oxygen element doping, the conductivity and energy level of the quantum dot may be regulated and controlled, such that an excellent composite condition of the electrons and the holes in the electroluminescent layer is found, thereby improving the brightness and EQE of the QLED.

In a first specific implementation of the present application, in ZnS₁₋ₓOₓ, 0.1≤x≤0.5; and the surface shell contains the oxygen with appropriate content, such that effective composite of the electrons and the holes in the quantum dot light-emitting layer is achieved.

In a second specific implementation of the present application, the mass percentage of oxygen in the core/shell quantum dot does not exceed 1%; and since the content of the oxygen is within a rational range, the conductivity of the core/shell quantum dot is more appropriate. Optionally, the content of the oxygen is 0.16%, 0.23%, 0.25%, 0.32%, 0.44%, 0.5%, 0.64%, 0.72%, or 0.78%.

In a third specific implementation of the present application, the surface shell is connected with surface ligand; and the surface ligand contains at least one of sulfhydryl, carboxyl, amino, an amide group, an organophosphine group, or an organic ester group. When the surface shell is connected with the surface ligand, the dispersibility of the core/shell quantum dot in the quantum dot light-emitting layer is better, thereby facilitating the subsequent preparation of the QLED.

The present application further provides a method for preparing a core/shell quantum dot for an LED. The preparation method includes a step of: at a certain temperature, introducing a gas containing oxygen into an initial quantum dot for reaction, so as to form a core/shell quantum dot, where the initial quantum dot includes a core body and a ZnS layer coating outside the core body; the core/shell quantum dot comprises the core body and a surface shell; and the surface shell is ZnS₁₋ₓOₓ, wherein 0.1≤x≤0.9. By means of partially oxidizing the ZnS layer of the initial quantum dot, the conductivity of the formed core/shell quantum dot is better, such that holes and electrons are better composited in the quantum dot light-emitting layer.

It is understandable that, in the initial quantum dot of the present application, the ZnS layer may include a plurality of ZnS molecular layers coating outside the core body. When the ZnS layer includes one ZnS molecular layer, after the gas containing oxygen is introduced into the initial quantum dot, the oxygen oxidizes some ZnS molecules in the ZnS molecular layer to form ZnO, so as to obtain the ZnS₁₋ₓOₓsurface shell. When the ZnS layer includes the plurality of ZnS molecular layers, after the gas containing oxygen is introduced into the initial quantum dot, the oxygen oxidizes some ZnS molecules in the outermost ZnS molecular layer away from the core body to form ZnO, so as to obtain the ZnS₁₋ₓOₓ surface shell.

In a preferred implementation, in the gas containing oxygen, the content percentage of the oxygen is 15-60%, such that the oxidation extent of the obtained core/shell quantum dot is more appropriate.

In a specific implementation, the gas is air. Using the air as an oxidizing agent may not only reduce production costs, but also obtain an appropriate reaction rate, such that the ZnS₁₋ₓOₓ surface shell which is partially oxidized is obtained quickly.

In another specific implementation, the flow rate of the gas is 0.1-1 L/min, such that an oxidation rate of the ZnS layer is adjusted, so as to obtain the ZnS₁₋ₓOₓ surface shell with the appropriate percentage of the oxygen. The flow rate of the gas is preferably 0.2-0.5 L/min.

In still another specific implementation, the temperature is 20-100° C. Under a low-temperature condition, the oxidation extent of the ZnS layer is better, and the interface of the surface shell is complete, facilitating the composite light emitting of the electrons and the holes in the core/shell quantum dot. The temperature is preferably 30-60° C.

In yet still another specific implementation, the core body includes a group II-VI compound, a group III-V compound, a group IV-VI compound, a group I-III-VI compound, a group I-II-IV-VI compound or a combination thereof. For example, the group II-VI compound may include CdSe, CdTe, ZnS, ZnSe, ZnTe, ZnO, HgS, HgSe, HgTe, MgSe, MgS, CdSeS, CdSeTe, CdSTe, ZnSeS, ZnSe Te, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, HgZnTeS, CdZnSeS, CdZnSeTe, CdZnSTe, CdHgSeS, CdHgSeTe, CdHgSTe, HgZnSeS, HgZnSeTe and HgZnSTe or a combination thereof. The group II-VI compound may further include group Ill metal. The group III-V compound may include GaN [symbol] GaP [symbol] GaAs [symbol] GaSb [symbol] AIN [symbol] AIP [symbol] AIAs [symbol] AISb [symbol] InN [symbol] InP [symbol] InAs [symbol] InSb [symbol] GaNP [symbol] GaNAs [symbol] GaNSb [symbol] GaPAs [symbol] GaPSb [symbol] AINP [symbol] AINAs [symbol] AINSb [symbol] AIPAS [symbol] AIPSb [symbol] InNP [symbol] InNAs [symbol] InNSb [symbol] InPAs [symbol] InPSb [symbol] InZnP [symbol] GaAINP [symbol] GaAINAs [symbol] GaAINSb [symbol] GaAIPAs [symbol] GaAIPSb [symbol] GaInNP [symbol] GaInNAs [symbol] GaInNSb [symbol] GaInPAs [symbol] GaInPSb [symbol] InAINP [symbol] InAINAs [symbol] InAINSb [symbol] InAIPAs [symbol] InAIPSb or a combination thereof. The group III-V compound may further include group II metal (for example, InZnP). The group IV-VI compound may include SnS [symbol] SnSe [symbol] SnTe [symbol] PbS [symbol] PbSe [symbol] PbTe [symbol] SnSeS [symbol] SnSe Te [symbol] SnSTe [symbol] PbSeS [symbol] PbSeTe [symbol] PbSTe [symbol] SnPbS [symbol] SnPbSe [symbol] SnPbTe [symbol] SnPbSSe [symbol] SnPbSeTe [symbol] SnPbSTe or a combination thereof. An example of the group I-III-VI compound may include CulnSe₂, CuInS₂, CuInGaSe and CuInGaS, but is not limited herein. An example of the group I-II-IV-VI compound may include CuZnSnSe and CuZnSnS, but is not limited herein. Coating the ZnS₁₋ₓOₓsurface shell on the core body improves the conductivity of the core/shell quantum dot.

In yet still another specific implementation, the dispersion liquid containing the initial quantum dot further includes at least one of a non-coordinating solvent, an aliphatic solvent and/or an aromatic solvent. Preferably, the non-coordinating solvent is selected from one or more of a group consisting of aliphatic hydrocarbon, aromatic hydrocarbon, chloroform, chlorobenzene, propylene glycol monomethyl ether acetate and hexanediol di-acrylate ester; the aliphatic hydrocarbon is selected from one or more of a group consisting of n-heptane, n-octane, n-hexane, 1-octadecene, 1-octadecane and 1-hexadecene; and the aromatic hydrocarbon is selected from toluene and/or benzene. The non-coordinating solvent includes at least one of aliphatic hydrocarbon or aromatic hydrocarbon, such that the ZnS layer of the initial quantum dot dispersed in the non-coordinating solvent is uniformly oxidized more easily, so as to form the ZnS₁₋ₓOₓsurface shell with better surface energy.

In a preferred implementation, the non-coordinating solvent of the present application is preferred at least one of n-hexane, n-heptane, toluene or 1-octadecene, facilitating a partial surface oxidation reaction on the initial quantum dot. The concentration of the initial quantum dot in the dispersion liquid is 10-100 mg/mL; by controlling the reaction rate of the oxygen, the concentration is preferably 20-50 mg/mL, such that the oxidation reaction rate of the surface shell is more appropriate.

The core/shell quantum dot of the present application is obtained by performing partial surface oxidation on the initial quantum dot, partial surface oxidation makes the conductivity of the core/shell quantum dot better, such that in the LED, the composite light emitting of the holes and the electrons in the quantum dot light-emitting layer is realized.

The present application further provides an LED. The LED includes a quantum dot light-emitting layer. The quantum dot light-emitting layer includes the core/shell quantum dot for an LED described above, or includes a core/shell quantum dot obtained by the method for preparing an LED described above.

The core/shell quantum dot and the LED of some exemplary implementations of the present application are described below in more detail; however, the exemplary implementations of the present application are not limited thereto.

### Embodiment 1

Purified red-light InP/ZnS quantum dot wasadded to n-heptane, so as to be prepared into a 20 mg/mL solution; 5 mL of the solution wasplaced to a reaction flask, and then a rubber stopper wasplugged in; a temperature wasset to 50° C.; and air waspumped into the solution by means of a needle by an air pump, an injection speed was0.25 L/min, the reaction wasperformed for 1 hour; a quantum dot of which wasInP/ZnS_{0.56}O_{0.44} is obtained after purification, and the mass percentage of the oxygen in the quantum dot was0.44%; and the quantum dot wasprepared as a 17 mg/mL n-octane solution, so as to prepare an LED, and the performance of the LED wastested.

### Embodiment 2

Purified red-light InP/ZnS quantum dot wasadded to n-heptane, so as to be prepared into a 20 mg/mL solution; 5 mL of the solution was placed to a reaction flask, and then a rubber stopper was plugged in; a temperature was set to 20° C.; and air was pumped into the solution by means of a needle by an air pump, an injection speed was 0.25 L/min, the reaction was performed for 1 hour; a quantum dot of which was ZnS_{0.68}O_{0.32} was obtained after purification, and the mass percentage of the oxygen in the quantum dot was0.32%; and the quantum dot was prepared as a 17 mg/ml n-octane solution, so as to prepare an LED, and the performance of the LED was tested.

### Embodiment 3

Purified red-light InP/ZnS quantum dot wasadded to n-heptane, so as to be prepared into a 20 mg/mL solution; 5 mL of the solution was placed to a reaction flask, and then a rubber stopper was plugged in; a temperature was set to 80° C.; and air was pumped into the solution by means of a needle by an air pump, an injection speed was 0.25 L/min, the reaction was performed for 1 hour; a quantum dot of which was ZnS_{0.28}O_{0.72} was obtained after purification, the mass percentage of the oxygen in the quantum dot was 0.72%, and the doping ratio of the oxygen was also verified by means of surface energy spectrum analysis; and the quantum dot was prepared as a 17 mg/ml n-octane solution, so as to prepare an LED, and the performance of the LED was tested.

### Embodiment 4

Purified red-light InP/ZnS quantum dot wasadded to n-heptane, so as to be prepared into a 20 mg/mL solution; 5 mL of the solution was placed to a reaction flask, and then a rubber stopper was plugged in; a temperature was set to 80° C.; and air was pumped into the solution by means of a needle by an air pump, an injection speed was 0.1 L/min, the reaction was performed for 1 hour; a quantum dot of which was ZnS_{0.75})_{0.25} was obtained after purification, and the mass percentage of the oxygen in the quantum dot was 0.25%; and the quantum dot was prepared as a 17 mg/ml n-octane solution, so as to prepare an LED, and the performance of the LED was tested.

### Embodiment 5

Purified red-light InP/ZnS quantum dot wasadded to n-heptane, so as to be prepared into a 20 mg/ml solution; 5 mL of the solution was placed to a reaction flask, and then a rubber stopper was plugged in; a temperature was set to 80° C.; and air was pumped into the solution by means of a needle by an air pump, an injection speed was 1 L/min, the reaction was performed for 1 hour; a quantum dot of which was ZnS_{0.22}O_{0.78} was obtained after purification, and the mass percentage of the oxygen in the quantum dot was 0.78%; and the quantum dot was prepared as a 17 mg/ml n-octane solution, so as to prepare an LED, and the performance of the LED was tested.

### Embodiment 6

Purified red-light InP/ZnS quantum dot wasadded to n-heptane, so as to be prepared into a 50 mg/mL solution; 5 mL of the solution was placed to a reaction flask, and then a rubber stopper was plugged in; a temperature was set to 80° C.; and air was pumped into the solution by means of a needle by an air pump, an injection speed was 1 L/min, the reaction was performed for 1 hour; a quantum dot of which was ZnS_{0.84}O_{0.16} was obtained after purification, and the mass percentage of the oxygen in the quantum dot was 0.16%; and the quantum dot was prepared as a 17 mg/ml n-octane solution, so as to prepare an LED, and the performance of the LED was tested.

### Embodiment 7

Purified red-light InP/ZnS quantum dot wasadded to n-heptane, so as to be prepared into a 20 mg/ml solution; 5 mL of the solution was placed to a reaction flask, and then a rubber stopper was plugged in; a temperature was set to 30° C.; and air was pumped into the solution by means of a needle by an air pump, an injection speed was 0.25 L/min, the reaction was performed for 1 hour; a quantum dot of which was ZnS_{0.66}O_{0.34} was obtained after purification; and the quantum dot was prepared as a 17 mg/mL n-octane solution, so as to prepare an LED, and the performance of the LED was tested.

### Embodiment 8

Purified red-light InP/ZnS quantum dot wasadded to n-heptane, so as to be prepared into a 20 mg/ml solution; 5 mL of the solution was placed to a reaction flask, and then a rubber stopper was plugged in; a temperature was set to 60° C.; and air was pumped into the solution by means of a needle by an air pump, an injection speed was 0.25 L/min, the reaction was performed for 1 hour; a quantum dot of which was ZnS_{0.036}O_{0.64} was obtained after purification; and the quantum dot was prepared as a 17 mg/mL n-octane solution, so as to prepare an LED, and the performance of the LED was tested.

### Embodiment 9

Purified red-light InP/ZnS quantum dot was added to 1-octadecene, so as to be prepared into a 20 mg/mL solution; 5 mL of the solution was placed to a reaction flask, and then a rubber stopper was plugged in; a temperature was set to 100° C.; and air was pumped into the solution by means of a needle by an air pump, an injection speed was 0.25 L/min, the reaction was performed for 1 hour; a quantum dot of which was ZnS_{0.10}O_{0.90} was obtained after purification; and the quantum dot was prepared as a 17 mg/mL n-octane solution, so as to prepare an LED, and the performance of the LED was tested.

### Embodiment 10

Purified red-light InP/ZnS quantum dot wasadded to n-heptane, so as to be prepared into a 10 mg/ml solution; 5 mL of the solution was placed to a reaction flask, and then a rubber stopper was plugged in; a temperature was set to 50° C.; and air was pumped into the solution by means of a needle by an air pump, an injection speed was 0.25 L/min, the reaction was performed for 1 hour; a quantum dot of which was InP/ZnS_{0.46}O_{0.54} was obtained after purification; and the quantum dot was prepared as a 17 mg/mL n-octane solution, so as to prepare an LED, and the performance of the LED was tested.

### Embodiment 11

Purified red-light InP/ZnS quantum dot wasadded to n-heptane, so as to be prepared into a 100 mg/ml solution; 5 mL of the solution was placed to a reaction flask, and then a rubber stopper was plugged in; a temperature was set to 50° C.; and air was pumped into the solution by means of a needle by an air pump, an injection speed was 0.25 L/min, the reaction was performed for 1 hour; a quantum dot of which was InP/ZnS_{0.90}O_{0.10} was obtained after purification; and the quantum dot was prepared as a 17 mg/mL n-octane solution, so as to prepare an LED, and the performance of the LED was tested.

### Embodiment 12

Purified red-light InP/ZnS quantum dot wasadded to n-heptane, so as to be prepared into a 20 mg/ml solution; 5 mL of the solution was placed to a reaction flask, and then a rubber stopper was plugged in; a temperature was set to 50° C.; and air was pumped into the solution by means of a needle by an air pump, an injection speed was 0.1 L/min, the reaction was performed for 1 hour; a quantum dot of which was InP/ZnS_{0.75}O_{0.25} was obtained after purification; and the quantum dot was prepared as a 17 mg/mL n-octane solution, so as to prepare an LED, and the performance of the LED was tested.

### Embodiment 13

Purified red-light InP/ZnS quantum dot wasadded to n-heptane, so as to be prepared into a 20 mg/mL solution; 5 mL of the solution was placed to a reaction flask, and then a rubber stopper was plugged in; a temperature was set to 50° C.; and air was pumped into the solution by means of a needle by an air pump, an injection speed was 0.5 L/min, the reaction was performed for 1 hour; a quantum dot of which was InP/ZnS_{0.39}O_{0.61} was obtained after purification; and the quantum dot was prepared as a 17 mg/mL n-octane solution, so as to prepare an LED, and the performance of the LED was tested.

### Embodiment 14

Purified red-light InP/ZnS quantum dot wasadded to n-heptane, so as to be prepared into a 20 mg/ml solution; 5 mL of the solution was placed to a reaction flask, and then a rubber stopper was plugged in; a temperature was set to 50° C.; and air was pumped into the solution by means of a needle by an air pump, an injection speed was 1 L/min, the reaction was performed for 1 hour; a quantum dot of which was InP/ZnS_{0.26}O_{0.72} was obtained after purification; and the quantum dot was prepared as a 17 mg/mL n-octane solution, so as to prepare an LED, and the performance of the LED was tested.

### Embodiment 15

Purified green-light InP/ZnS quantum dot wasadded to n-heptane, so as to be prepared into a 20 mg/mL solution; 5 mL of the solution was placed to a reaction flask, and then a rubber stopper was plugged in; a temperature was set to 50° C.; and air was pumped into the solution by means of a needle by an air pump, an injection speed was 0.25 L/min, the reaction was performed for 1 hour; a quantum dot of which was InP/ZnS_{0.56}O_{0.44} was obtained after purification, and the mass percentage of the oxygen in the quantum dot was 0.23%; and the quantum dot was prepared as a 15mg/ml n-octane solution, so as to prepare an LED, and the performance of the LED was tested.

### Embodiment 16

Purified blue-light ZnSe/ZnS quantum dot wasadded to n-heptane, so as to be prepared into a 20 mg/ml solution; 5 mL of the solution was placed to a reaction flask, and then a rubber stopper was plugged in; a temperature was set to 30° C.; and air was pumped into the solution by means of a needle by an air pump, an injection speed was 1 L/min, the reaction was performed for 1 hour; a quantum dot of which was ZnS_{0.52}O_{0.48} was obtained after purification, and the mass percentage of the oxygen in the quantum dot was 0.64%; and the quantum dot was prepared as a 13 mg/ml n-octane solution, so as to prepare an LED, and the performance of the LED was tested.

### Embodiment 17

Purified red-light CdSe/ZnS quantum dot wasadded to n-heptane, so as to be prepared into a 20 mg/ml solution; 5 mL of the solution was placed to a reaction flask, and then a rubber stopper was plugged in; a temperature was set to 30° C.; and air was pumped into the solution by means of a needle by an air pump, an injection speed was 1 L/min, the reaction was performed for 1 hour; a quantum dot of which was ZnS_{0.64}O_{0.36} was obtained after purification, and the mass percentage of the oxygen in the quantum dot was 0.5%; and the quantum dot was prepared as a 15 mg/ml n-octane solution, so as to prepare an LED, and the performance of the LED was tested.

### Comparative example 1

Purified red-light InP/ZnS quantum dot was prepared as a 17 mg/ml n-octane solution, so as to prepare an LED, and the performance of the LED was tested.

### Comparative Example 2

Purified green-light InP/ZnS quantum dot was prepared as a 17 mg/mL n-octane solution, so as to prepare an LED, and the performance of the LED was tested.

### Comparative Example 3

Purified blue-light ZnSe/ZnS quantum dot was prepared as a 13 mg/mL n-octane solution, so as to prepare an LED, and the performance of the LED was tested.

### Comparative Example 4

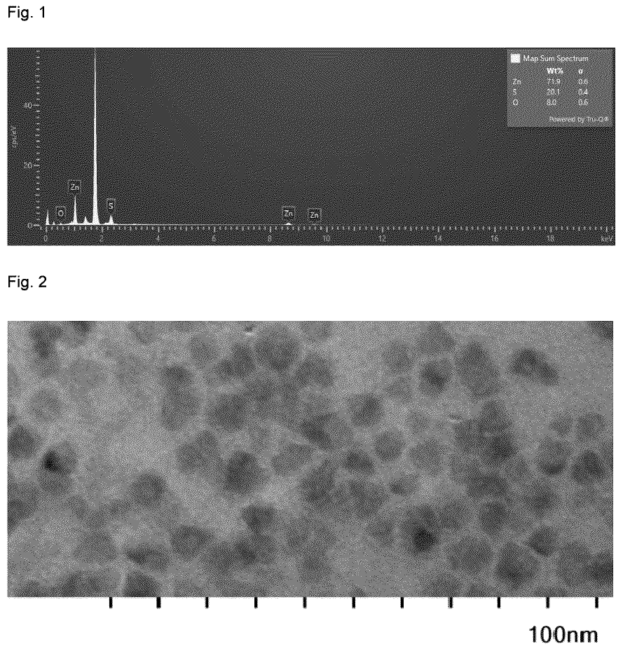

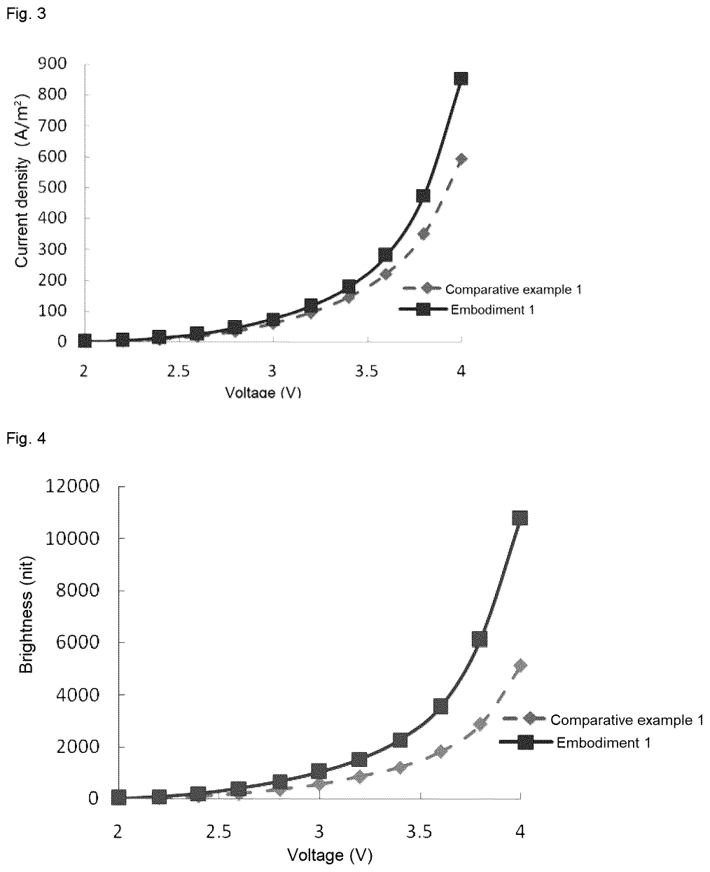

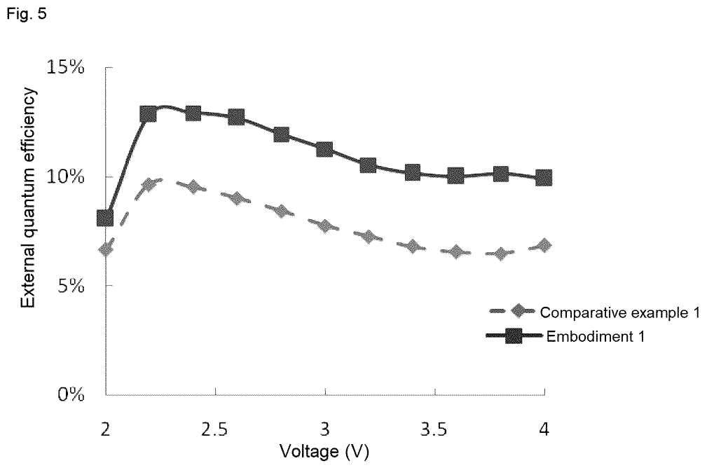

Purified red-light CdSe/ZnS quantum dot was prepared as a 15 mg/ml n-octane solution, so as to prepare an LED, and the current density, brightness and maximum EQE of the LED at 3V are tested. A specific result is shown in Table 1. FIG. 1 is a surface energy spectrum analysis diagram of a core/shell quantum dot according to Embodiment 1, and it can be learned that, the surface shell included by the core/shell quantum dot is ZnS_{0.56}O_{0.44}. FIG. 2 is a scanning electron microscope diagram of the core/shell quantum dot according to Embodiment 1, and it can be learned that the particle size of the core/shell quantum dot is about 8 nm. FIGS. 3-5 show a comparison relationship of voltage-current density, voltage-brightness, and voltage-EQE in Embodiment 1 and Comparative example 1. Performance parameters of the LED including the quantum dot with an InP core in Embodiments 1-14 and Comparative example 1 are shown in Table 1. Performance parameters of the LED including the quantum dot with the InP core in Embodiment 15 and Comparative example 2 are shown in Table 2. Performance parameters of the LED including the quantum dot with a ZnSe core in Embodiment 16 and Comparative example 3 are shown in Table 3. Performance parameters of the LED including the quantum dot with a CdSe core in Embodiment 17 and Comparative example 4 are shown in Table 4.

TABLE 1
Performance parameters of LED including quantum dot with
InP core in Embodiments 1-14 and Comparative example 1

| | 3 V current | 3 V brightness | Maximum |
|---|---|---|---|
| No. | density (A/m²) | (nits) | EQE (%) |
| Embodiment 1 | 73 | 1031 | 12.91 |
| Embodiment 2 | 68 | 835 | 12.81 |
| Embodiment 3 | 124 | 1548 | 11.95 |
| Embodiment 4 | 64 | 839 | 13.39 |
| Embodiment 5 | 135 | 1987 | 13.24 |
| Embodiment 6 | 62 | 995 | 15.03 |
| Embodiment 7 | 34 | 685 | 10.58 |
| Embodiment 8 | 120 | 1452 | 12.21 |
| Embodiment 9 | 215 | 2675 | 11.91 |
| Embodiment 10 | 86 | 1231 | 12.82 |
| Embodiment 11 | 62 | 867 | 14.52 |
| Embodiment 12 | 68 | 898 | 15.63 |
| Embodiment 13 | 112 | 1451 | 12.13 |
| Embodiment 14 | 151 | 1876 | 13.01 |
| Comparative example 1 | 58 | 556 | 9.64 |

TABLE 2
Performance parameters of LED including quantum dot with
InP core in Embodiment 15 and Comparative example 2

| | 3 V current | 3 V brightness | Maximum |
|---|---|---|---|
| No. | density (A/m²) | (nits) | EQE (%) |
| Embodiment 15 | 24 | 1321 | 14.01 |
| Comparative example 2 | 4 | 179 | 10.12 |

TABLE 3
Performance parameters of LED including quantum dot with
ZnSe core in Embodiment 16 and Comparative example 3

| | 3 V current | 3 V brightness | Maximum |
|---|---|---|---|
| No. | density (A/m²) | (nits) | EQE (%) |
| Embodiment 16 | 24 | 191 | 13.42 |
| Comparative example 3 | 6 | 4 | 6.44 |

TABLE 4
Performance parameters of LED including quantum dot with
CdSe core in Embodiment 17 and Comparative example 4

| | 3 V current | 3 V brightness | Maximum |
|---|---|---|---|
| No. | density (A/m²) | (nits) | EQE (%) |
| Embodiment 17 | 886 | 14550 | 15.08 |
| Comparative example 4 | 246 | 5890 | 11.25 |

From Tables 1-3 and FIGS. 1-5, it can be learned that, compared with Comparative examples 1-4, when the core/shell quantum dot of Embodiments 1-17 of the present application is used to prepare the light-emitting layer of the LED, the electrical property of the obtained LED is excellent, and current efficiency, brightness and EQE efficiency are significantly improved.

Although the inventor has described and enumerated the technical solutions of the present application in some detail, it should be understood that it is apparent to a person skilled in the art to make modifications and/or adaptations to the above embodiments or to adopt equivalent alternative solutions, none of which can depart from the essence of the spirit of the present application, and the terms appearing in the present application are used in the description and understanding of the technical solutions of the present application and do not constitute a limitation of the present application.

What is claimed is:

1. A core/shell quantum dot for a Light-Emitting Diode (LED), comprising a core body and a surface shell, the surface shell is ZnS₁₋ₓOₓ, wherein 0.1≤x≤0.9.

2. The core/shell quantum dot for an LED according to claim 1, wherein in ZnS₁₋ₓOₓ, 0.1≤x≤0.5.

3. The core/shell quantum dot for an LED according to claim 1, wherein a mass percentage of oxygen in the core/shell quantum dot does not exceed 1%.

4. The core/shell quantum dot for an LED according to claim 1, wherein the surface shell is connected with surface ligand; and the surface ligand contains at least one of sulfhydryl, carboxyl, amino, amide, organophosphine, or organic ester.

5. A method for preparing a core/shell quantum dot for an LED, comprising a step of:
at a certain temperature, introducing a gas containing oxygen into dispersion liquid containing an initial quantum dot for reaction, so as to form thecore/shell quantum dot, wherein the initial quantum dot comprises a core body and a ZnS layer coating outside the core body; the core/shell quantum dot comprises the core body and a surface shell; and the surface shell is ZnS₁₋ₓOₓ, wherein 0.1≤x≤0.9.

6. The method for preparing a core/shell quantum dot for an LED according to claim 5, wherein the gas is air.

7. The method for preparing a core/shell quantum dot for an LED according to claim 5, wherein the flow rate of the gas is 0.1-1 L/min.

8. The method for preparing a core/shell quantum dot for an LED according to claim 5, wherein the temperature is 20-100° C.

9. The method for preparing a core/shell quantum dot for an LED according to claim 5, wherein the dispersion liquid further contains a non-coordinating solvent, and the non-coordinating solvent contains at least one of an aliphatic solvent and/or an aromatic solvent; preferably, the non-coordinating solvent is selected from one or more of a group consisting of aliphatic hydrocarbon, aromatic hydrocarbon, chloroform, chlorobenzene, propylene glycol monomethyl ether acetate and hexanediol di-acrylate ester, wherein the aliphatic hydrocarbon is selected from one or more of a group consisting of heptane, n-octane, hexane, 1-octadecene, octadecane and 1-hexadecene, and the aromatic hydrocarbon is selected from toluene and/or benzene; and
preferably, in the dispersion liquid, the concentration of the initial quantum dot is 10-100 mg/mL, more preferably 10-50 mg/mL.

10. An LED, comprising a quantum dot light-emitting layer, wherein the quantum dot light-emitting layer comprises the core/shell quantum dot for an LED according to claims 1.

11. The LED according to claim 10, wherein in ZnS₁₋ₓOₓ, 0.1≤x≤0.5.

12. The LED according to claim 10, wherein a mass percentage of oxygen in the core/shell quantum dot does not exceed 1%.

13. The LED according to claim 10, wherein the surface shell is connected with surface ligand; and the surface ligand contains at least one of sulfhydryl, carboxyl, amino, amide, organophosphine, or organic ester.

14. The LED according to claim 10, wherein the quantum dot light-emitting layer comprises the core/shell quantum dotobtained by the method for preparing an LED, comprising a step of:
at a certain temperature, introducing a gas containing oxygen into dispersion liquid containing an initial quantum dot for reaction, so as to form the core/shell quantum dot, wherein the initial quantum dot comprises a core body and a ZnS layer coating outside the core body; the core/shell quantum dot comprises the core body and a surface shell; and the surface shell is ZnS₁₋ₓOₓ, wherein 0.1≤x≤0.9.

15. The LED according to claim 14, wherein the gas is air.

16. The LED according to claim 14, wherein the flow rate of the gas is 0.1-1 L/min.

17. The LED according to claim 14, wherein the temperature is 20-100° C.

18. The LED according to claim 14, wherein the dispersion liquid further contains a non-coordinating solvent, and the non-coordinating solvent contains at least one of an aliphatic solvent and/or an aromatic solvent; preferably, the non-coordinating solvent is selected from one or more of a group consisting of aliphatic hydrocarbon, aromatic hydrocarbon, chloroform, chlorobenzene, propylene glycol monomethyl ether acetate and hexanediol di-acrylate ester, wherein the aliphatic hydrocarbon is selected from one or more of a group consisting of heptane, n-octane, hexane, 1-octadecene, octadecane and 1-hexadecene, and the aromatic hydrocarbon is selected from toluene and/or benzene; andpreferably, in the dispersion liquid, the concentration of the initial quantum dot is 10-100 mg/mL, more preferably 10-50 mg/mL.
